(19) United States
(12) Patent Application Publication
(10) Pub. No.: US 2026/0058435 A1
(43) Pub. Date: Feb. 26, 2026

(54) SEMICONDUCTOR LASER DEVICE

(71) Applicant: SHARP KABUSHIKI KAISHA, Sakai City (JP)

(72) Inventors: Kazutaka Matsumoto, Sakai City (JP); Kiyoshi Inoue, Sakai City (JP); Minoru Taguchi, Sakai City (JP); Kyohichi Miyazaki, Sakai City (JP)

(21) Appl. No.: 19/297,489

(22) Filed: Aug. 12, 2025

(30) Foreign Application Priority Data
Aug. 21, 2024 (JP) 2024-139871

(51) Int. Cl. H01S 5/0239; H02H 9/04

(52) U.S. Cl. CPC H01S 5/0239; H02H 9/04

(57) ABSTRACT

A semiconductor laser device comprises a laser light-emitting element that emits laser light; a first electrostatic protection element connected to the laser light-emitting element and having a fast response; and a second electrostatic protection element connected in parallel to the first electrostatic protection element and having a response slower than the first electrostatic protection element.

### CROSS-REFERENCE TO RELATED APPLICATION

The present application claims priority from Japanese Application JP2024-139871, the content of which is hereby incorporated by reference into this application.

### BACKGROUND

### 1. Field

The present disclosure relates to a semiconductor laser device using a laser light-emitting element.

### BACKGROUND ART

In the related art, upon assembling a semiconductor laser device using a laser light-emitting element, there is a risk that static electricity may be transmitted to the laser light-emitting element and may cause electrostatic damage of the laser light-emitting element. Even if the laser light-emitting element is not completely damaged, a light-emitting end face of the laser light-emitting element is damaged. As a result, there is a problem in that the life of the laser light-emitting element is reduced and reliability cannot be obtained. As a countermeasure against such a problem, in the related art, it has been known that a Zener diode is connected in parallel to the laser light-emitting element to prevent a surge voltage from being applied to the laser light-emitting element.

In addition, in the related art, it has been known that a light amount control device, including a light amount controller that controls a light amount of a multi-laser light source based on a voltage detected by a light detector that detects the light amount of the multi-laser light source as a voltage, is further provided with an overvoltage prevention unit that prevents the voltage detected by the light detector from exceeding a predetermined voltage value.

Further, in the related art, a light-emitting diode element having a function of protecting a light-emitting diode chip from electrostatic discharge, and a method of manufacturing the light-emitting diode element are also known.

### SUMMARY

FIG. 4 is a diagram illustrating a waveform of an electrostatic surge voltage. In the diagram, the X-axis represents the time and the Y-axis represents the voltage. As illustrated in FIG. 4, the waveform of the electrostatic surge voltage has a first half in which the electrostatic surge voltage rises rapidly in the order of ns, and a second half in which the electrostatic surge voltage transitions in the order of μs.

FIG. 5 is a diagram illustrating an effective range for suppressing the surge voltage when the electrostatic surge voltage is suppressed only by a Zener diode. In the drawing, the X-axis represents the time and the Y-axis represents the voltage. As described above, the Zener diode used for protecting the laser light-emitting element has a Zener voltage of 2 to 3 V in consideration of an operating voltage of the laser light-emitting element. The Zener diode has a slow response and is effective for protection against overvoltage pulses of μs or more, but cannot protect the laser light-emitting element against an electrostatic surge voltage of less than μs.

Therefore, in FIG. 5, a first half of the surge voltage indicated by a solid line cannot be dealt with by the Zener diode due to the response of the Zener diode being too slow, and only a second half of the surge voltage indicated by a dotted line is dealt with by the Zener diode.

Meanwhile, a transient voltage suppressor (TVS) diode is also available as a diode suitable for protection against the electrostatic surge voltage. Although the TVS diode has a fast response, the TVS diode cannot provide protection against the electrostatic surge voltage unless the Zener voltage is set to a reasonably large voltage (5 V or more). In addition, since the technical difficulty is high with the TVS diode, there has been a problem in that the TVS diode is not effective for protection against overvoltage pulses of μs or more and 2 to 3 V or more.

The present disclosure has been made to solve the above-described problems, and an object of the present disclosure is to provide a semiconductor laser device including a laser light-emitting element in which, even when a surge voltage is applied, end face damage due to a large current flowing through the laser light-emitting element does not occur.

A semiconductor laser device according to the present disclosure includes a laser light-emitting element that emits laser light, a first electrostatic protection element connected to the laser light-emitting element and having a fast response, and a second electrostatic protection element connected in parallel to the first electrostatic protection element and having a response slower than the first electrostatic protection element.

The first electrostatic protection element is preferably disposed close to the laser light-emitting element.

The first electrostatic protection element may be a TVS diode, and the second electrostatic protection element may be a Zener diode.

According to the present disclosure, since the semiconductor laser device is connected to the laser light-emitting element and includes the first electrostatic protection element having the fast response and the second electrostatic protection element connected in parallel to the first electrostatic protection element and having the response slower than the first electrostatic protection element, even when a surge voltage is applied, an electrostatic surge voltage of less than μs can be suppressed by the first electrostatic protection element having the fast response, and protection against overvoltage pulses of μs or more and 2 to 3 V or more can be achieved by the second electrostatic protection element having the response slower than the first electrostatic protection element.

As a result, it is possible to provide a semiconductor laser device including a laser light-emitting element in which, even when a surge voltage is applied, end face damage due to a large current flowing through the laser light-emitting element does not occur.

The above-described objects, other objects, features, and advantages of the present disclosure will be further obvious from the detailed description of examples given below with reference to the drawings.

### BRIEF DESCRIPTION OF THE DRAWINGS

FIG. 1 is a circuit diagram illustrating a case where a semiconductor laser device including a laser light-emitting element according to the present disclosure is mounted on a substrate.

FIG. 2 is a diagram illustrating a surge voltage waveform in a case where an electrostatic surge voltage is suppressed by a TVS diode and a Zener diode when the semiconductor laser device including the laser light-emitting element illustrated in FIG. 1 is mounted on the substrate.

FIG. 3 is a diagram illustrating a CAN package of the laser light-emitting element.

FIG. 4 is a diagram illustrating a waveform of the electrostatic surge voltage.

FIG. 5 is a diagram illustrating an effective range for suppressing the surge voltage when the electrostatic surge voltage is suppressed only by the Zener diode.

### DESCRIPTION OF EMBODIMENTS

### First Embodiment

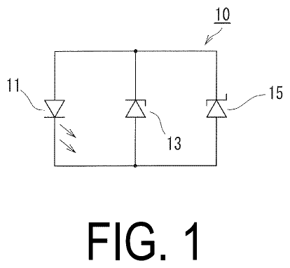

Embodiments according to the present disclosure will be described in detail below with reference to the drawings. FIG. 1 is a circuit diagram illustrating a case where a semiconductor laser device including a laser light-emitting element according to the present disclosure is mounted on a substrate. Referring to FIG. 1, a semiconductor laser device 10 according to the present disclosure includes a laser light-emitting element 11, a TVS diode 13 having a fast response, and a Zener diode 15 having a slow response, which are connected in parallel to one another.

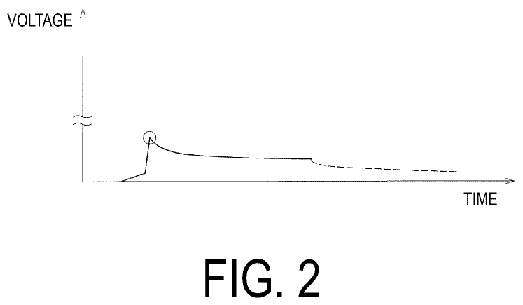

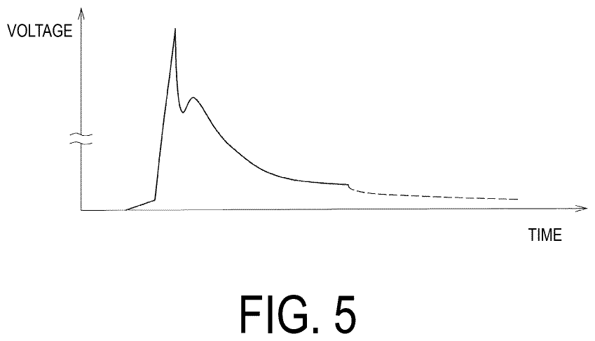

Next, effects of the semiconductor laser device 10 according to the present disclosure will be described. FIG. 2 is a diagram illustrating a waveform of a surge voltage in a case where an electrostatic surge voltage is suppressed by the TVS diode 13 and the Zener diode 15 when the semiconductor laser device 10 including the laser light-emitting element 11 illustrated in FIG. 1 is mounted on the substrate. In FIG. 2, the X-axis represents the time and the Y-axis represents the voltage. Referring to FIG. 2, in the semiconductor laser device 10 according to the present disclosure, by using the TVS diode 13, a peak value of a first half of the surge voltage, indicated by a solid line, is set to a value indicated by a circle so that a rapid rise of the surge voltage does not occur as in the related art, and by using the Zener diode 15, a second half of the surge voltage, indicated by a dotted line, can be set to be similar to a surge voltage of the related art illustrated in FIG. 5.

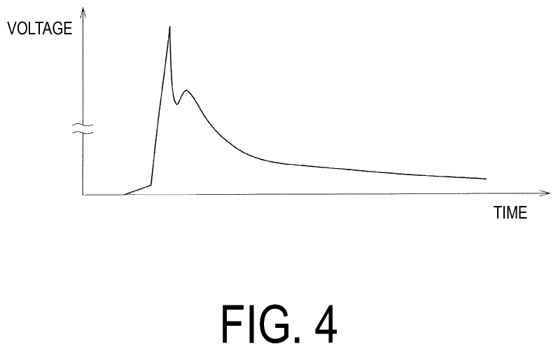

That is, in the present disclosure, since the TVS diode 13 having the fast response is also connected in parallel together with the Zener diode 15 having the slow response, the first half, which is a section in which the surge voltage rapidly rises as illustrated in FIG. 4, can be suppressed by the TVS diode 13 that responds in a short time (ns) of less than μs, and protection against overvoltage pulses of μs or more and 2 to 3 V or more in the second half can be achieved by the Zener diode 15.

As a result, even if a surge voltage is applied to the laser light-emitting element of the semiconductor laser device, end face damage due to a large current flowing through the laser light-emitting element does not occur.

### Second Embodiment

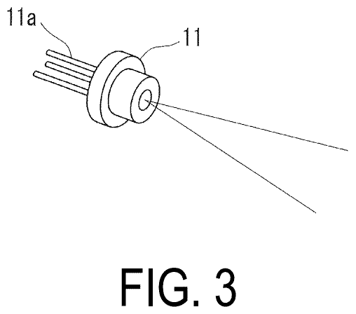

Next, a specific arrangement of the laser light-emitting element 11 and the TVS diode 13 will be described. FIG. 3 is a diagram illustrating a CAN package of the laser light-emitting element 11. Structurally, a leg 11a of the CAN package acts like a lightning conductor, and thus the leg 11a is likely to attract static electricity. Therefore, by disposing the TVS diode 13 (not illustrated) having the fast response at a position closest to the leg 11a of the CAN package of the laser light-emitting element 11 illustrated in FIG. 3, the peak voltage of the surge voltage can be further reduced.

As a result, in the present disclosure, by disposing the TVS diode 13 having the fast response at a position closer to a portion of the laser light-emitting element 11 to which electrostatic pulses are applied, the TVS diode 13 is less likely to be affected by the wiring impedance of the substrate, and the peak voltage of the surge voltage can be further reduced.

As described above, in the present disclosure, the first half of the electrostatic surge voltage is protected by using a first electrostatic protection element, such as a TVS diode, having a fast response that responds in ns or less, and the second half of the electrostatic surge voltage is protected by a second electrostatic protection element, such as a Zener diode, having a slower response than the first electrostatic protection element.

As a result, the first half of the electrostatic surge voltage can be suppressed in a similar manner to the second half, and the probability of the life of the laser light-emitting element being reduced due to damage to a light-emitting end face of the laser light-emitting element can be further reduced.

Note that, in the above-described embodiment, the case is described where the TVS diode and the Zener diode are respectively used as the first electrostatic protection element having the fast response and the second electrostatic protection element having the slow response. However, the configuration is not limited thereto, and any one of a serial regulator, an LDO, a shunt regulator, a Schottky diode, and a switching diode may be used as the first or second electrostatic protection element, in accordance with the speed of response.

The present disclosure may be carried out in other various forms without departing from the spirit or essential characteristics thereof. Thus, the above-described embodiments are merely examples and should not be interpreted as limiting.

All modifications and changes equivalent in scope with the claims of the present disclosure are included in the scope of the present disclosure.

### INDUSTRIAL APPLICABILITY

According to the present disclosure, it is possible to provide a semiconductor laser device using a laser light-emitting element in which, even when a surge voltage is applied, end face damage due to a large current flowing through the laser light-emitting element does not occur. Thus, the present disclosure is useful as a semiconductor laser device.

1. A semiconductor laser device comprising:
a laser light-emitting element that emits laser light;
a first electrostatic protection element connected to the laser light-emitting element and having a fast response; and
a second electrostatic protection element connected in parallel to the first electrostatic protection element and having a response slower than the first electrostatic protection element.

2. The semiconductor laser device according to claim 1, wherein
the first electrostatic protection element is disposed close to the laser light-emitting element.

3. The semiconductor laser device according to claim 1, wherein
the first electrostatic protection element is a TVS diode, and
the second electrostatic protection element is a Zener diode.
